(19) United States
(12) Patent Application Publication
(10) Pub. No.: US 2010/0206374 A1
(43) Pub. Date: Aug. 19, 2010

(54) PLASTICIZED FILMS BASED ON POLYVINYL ACETAL HAVING AN INCREASED GLASS TRANSITION TEMPERATUARE AND IMPROVED FLOW PROPERTIES

(75) Inventors: Andreas Karpinski, Odenthal (DE); Uwe Keller, Bonn (DE); Martin Steuer, Liederbach (DE); Holger Stenzel, Hennef (DE)

Correspondence Address: BROOKS KUSHMAN P.C., 1000 TOWN CENTER, TWENTY-SECOND FLOOR, SOUTHFIELD, MI, 48075, US

(73) Assignee: KURARAY EUROPE GMBH, Frankfurt am Main (DE)

(21) Appl. No.: 12/680,140

(22) PCT Filed: Oct. 6, 2008
(86) PCT No.: PCT/EP08/63304

§ 371 Date: Mar. 25, 2010

(30) Foreign Application Priority Data
Oct. 5, 2007 (DE) 10 2007 000 817.3

(51) Int. Cl. H01L 31/00; C08L 29/14

(52) U.S. Cl. 136/256; 524/543

(57) ABSTRACT

Plasticizer-containing films of polyvinyl acetal having a plasticizer content of a maximum of 26% by weight and containing a mixture of at least one high-viscosity polyvinyl acetal having a viscosity of 40-300 mPas and at least one low-viscosity polyvinyl acetal having a viscosity of 5-500 mPas are suitable for the production of photovoltaic modules.

### TECHNICAL FIELD

The invention relates to the production of photovoltaic modules using plasticizer-containing films based on polyvinyl acetal having an increased glass transition temperature and improved flow behavior.

### PRIOR ART

Photovoltaic modules consist of a photosensitive semiconductor layer that is provided with a transparent covering as a protection against external effects. As photosensitive semiconductor layer, monocrystalline solar cells or supported polycrystalline, thin semiconductor layers can be used. Thin-film solar modules consist of a photosensitive semiconductor layer applied to a mostly transparent sheet by means of for example evaporation coating, chemical vapor deposition, sputtering, or wet deposition.

Both systems are normally laminated between a glass panel and a rigid, rear covering panel made for example of glass or plastics by means of a transparent adhesive.

The transparent adhesive must completely enclose the photosensitive semiconductor layer and its electrical interconnections, must be UV stable and moisture insensitive, and must be completely bubble-free after the lamination process.

As transparent adhesive, thermosetting casting resins or cross-linkable, ethylene vinyl acetate—(EVA)—based systems are often used, such as for example disclosed in DE 22 721 C1 or DE 41 28 766 A1. In the uncured state, these adhesive systems can be adjusted to such a low viscosity that they enclose the solar cell units bubble-free. After addition of a curing or cross-linking agent, a mechanically robust adhesive layer is obtained. A disadvantage of these adhesive systems is that during the curing process, aggressive substances, such as acids, which may destroy the photosensitive semiconductor layers, in particular thin-film modules, are often released. In addition, some casting resins tend to form bubbles or delaminate after a few years as a result of UV radiation.

An alternative to thermosetting adhesive systems is the use of plasticizer-containing films based on polyvinyl acetals, such as polyvinyl butyral (PVB) known from the manufacturing of laminated glass. The solar cell units are covered with one or more PVB films, and the films are bonded with the desired covering materials to a laminate under elevated pressure and temperature.

Methods for the production of solar modules using PVB films are known for example from DE 40 26 165 C2, DE 42 278 60 A1, DE 29 237 70 C2, DE 35 38 986 C2, or U.S. Pat. No. 4,321,418. The use of PVB films in solar modules as laminated safety glass is disclosed for example in DE 20 302 045 U1, EP 1617487 A1, and DE 35 389 86 C2. These documents, however, do not contain any information about the mechanical, chemical, and electrical properties of the PVB films used.

The electrical properties of the adhesive films in particular become more and more important with increasing efficiency of the photosensitive semiconductor layers and global distribution of solar modules. Leakage currents or even short circuits of the semiconductor layer must also be avoided under extreme weather conditions, such as tropical temperatures, high humidity, or heavy UV radiation, over the entire lifetime of the module. According to CEI 61215, photovoltaic modules are subjected to numerous tests (damp heat test, wet leakage current test) in order to reduce leakage currents of the modules. In order to achieve this, the adhesive films need to have a resistivity that is as high as possible.

It was found that suitable adhesive films having high resistivity also have an increased glass transition temperature Tg. Without being bound to the correctness of the theory, this is attributed to reduced ion mobility in a glass-like or high-viscosity environment.

The glass transition temperature Tg of plasticizer-containing films based on polyvinyl acetal is largely determined by the content and the polarity of the plasticizer used. As a result, the resistivity of the film can be adjusted in a simple manner by reducing the plasticizer content.

However, an increase of the glass transition temperature Tg of a plasticizer-containing film based on polyvinyl acetal normally leads to a reduction of its flowability. The film can become so highly viscous, even under elevated temperature, that in a photovoltaic module, a complete encapsulation or enveloping of the photosensitive semiconductor layers can no longer occur. In the extreme case, processing into a laminate is hardly possible any longer.

### OBJECT

Object of the present invention is therefore to provide plasticizer-containing films based on polyvinyl acetal having an increased glass transition temperature Tg and hence increased (electrical) resistivity, and sufficient flowability for the production of photovoltaic modules.

Surprisingly, it was found that plasticizer-containing films based on polyvinyl acetal having an increased glass transition temperature Tg have a flowability sufficient for processing into laminated glasses or photovoltaic modules if mixtures of low-viscosity and high-viscosity polyvinyl acetals are used for the production thereof.

### PRESENTATION OF THE INVENTION

Subject matter of the present invention is therefore photovoltaic modules comprising a laminate of

a) a transparent front covering

b) one or more photosensitive semiconductor layers

c) at least one plasticizer-containing film based on polyvinyl acetal, and

d) a back covering,

the plasticizer-containing films based on polyvinyl acetal c) having a plasticizer content of a maximum of 26% by weight and comprising a mixture of at least one high-viscosity polyvinyl acetal having a viscosity of 40-300 mPas and at least one low-viscosity polyvinyl acetal having a viscosity of 5-500 mPas.

A further subject matter of the invention is plasticizer-containing films containing polyvinyl acetal, the films having a plasticizer content of a maximum of 26% by weight and comprising a mixture of at least one high-viscosity polyvinyl acetal having a viscosity of 40-300 mPas and at least one low-viscosity polyvinyl acetal having a viscosity of 5-500 mPas.

The films used according to the invention preferably exhibit at an ambient humidity of 85% RH at 23° C. a resistivity of at least 1E+11 ohm*cm, preferably at least 5E+11 ohm*cm, preferably 1E+12 ohm*cm, preferably 5E+12 ohm*cm, preferably 1E+13, preferably 5E+13 ohm*cm, preferably 1E+14 ohm*cm. These values should be achieved at any position of the film, in particular in the edge regions of the module.

The glass transition temperature Tg of the films according to the invention or used according to the invention is preferably in each case at least 20° C., 22° C., 24° C., 26° C., 27° C., 30° C., or 35° C. As maximum for the glass transition temperature Tg, 40° C. can be specified.

According to the invention, the reduced flowability of the films usually associated with an increase of the glass transition temperature Tg can be adjusted to a suitable value by mixing high-viscosity and low-viscosity polyvinyl acetals. This is easily done by those skilled in the art using exploratory trials.

Since the flowability or viscosity of the film mixtures also depends on the type and quantity of plasticizer used, only mixtures with the same plasticizer may be compared with each other.

For guidance with respect to the type and quantities of high-viscosity and low-viscosity polyvinyl acetals used, it applies that a high content of a polyvinyl acetal having a high viscosity can be balanced by a polyvinyl acetal having an especially low viscosity in order to adjust a flowability sufficient for processing of the film.

The following equations I and II allow those skilled in the art to adjust the flowability of plasticizer-containing polyvinyl acetals to a desired value in a simple manner without significantly changing the glass transition temperature Tg. According to the invention, this is possible by adding low-viscosity to high-viscosity polyvinyl acetal (or vice versa), since only the flowability of the mixture but not its glass transition temperature Tg is affected hereby.

Films according to the invention having a predetermined glass transition temperature Tg of at least 20° C. therefore preferably have at least a melt mass flow rate (MFR) in accordance with one or both of equations I and II:

MFR at 100° C.≧A−0.0133×Tg×[10 min/(g×° C.)] I

MFR at 140° C.≧B−0.67×Tg×[10 min/(g×° C.)] II

The MFR is specified in the unit g/10 min, Tg is specified in ° C., and A and B have the unit g/10 min.

In films according to the invention, A preferably has a value of at least 0.52, more preferably at least 0.57, at least 0.62, and most preferably at least 0.67.

Analogously, B preferably has a value of at least 23, more preferably at least 25, and most preferably at least 27.

The viscosity measurements within the scope of the present invention are performed for both components of the mixture in accordance with DIN 53015 in ethanol at 20° C., the ethanol containing 5% by weight of water. The measurement of the high-viscosity polyvinyl acetal is performed in a 5% by weight solution, the measurement of the low-viscosity polyvinyl acetal in a 10% by weight solution. The viscosity of the high-viscosity polyvinyl acetal exceeds the viscosity of the low-viscosity polyvinyl acetal, so that different polyvinyl acetals have to be used according to the invention.

The high-viscosity polyvinyl acetal preferably has a viscosity of 40-200 mPas, most preferably 50-100 mPas; the low-viscosity polyvinyl acetal independently thereof preferably has a viscosity of 10-400 mPas, more preferably 10-300 mPas or 10-200 mPas, and most preferably 10-100 mPas.

The mixtures used according to the invention preferably comprise at least one high-viscosity polyvinyl acetal having a viscosity of 50-100 mPas and at least one low-viscosity polyvinyl acetal having a viscosity of 10-100 mPas (measurements are performed as described above). In mixtures of this type, the high-viscosity polyvinyl acetal and the low-viscosity polyvinyl acetal may be used in a weight ratio with respect to one another of 1:1 to 19:1, preferably 2:1 to 9:1, and more preferably 2:1 to 4:1.

The films based on plasticizer-containing polyvinyl acetal preferably contain uncrosslinked polyvinyl butyral (PVB) obtained by acetalizing polyvinyl alcohol with butyraldehyde.

The use of crosslinked polyvinyl acetals, in particular crosslinked polyvinyl butyral (PVB), is also possible. Suitable crosslinked polyvinyl acetals are described for example in EP 1527107 B1 and WO 2004/063231 A1 (thermal self-crosslinking of carboxyl group-containing polyvinyl acetals), EP 1606325 A1 (polyvinyl acetals crosslinked with polyaldehydes), and WO 03/020776 A1 (Polyvinyl acetals crosslinked with glyoxylic acid). The disclosure of these patent applications is fully incorporated herein by reference.

It is also possible to perform the acetalization using other or additional aldehydes having 5-10 carbon atoms (such as for example valeraldehyde). The high-viscosity and low-viscosity polyvinyl acetals are obtained by acetalization with the same aldehydes.

Terpolymers of hydrolyzed vinyl acetate/ethylene copolymers can also be used as polyvinyl alcohol within the scope of the invention. These compounds are normally hydrolyzed to more than 98% and contain 1 to 10% by weight of ethylene-based units (for example type “Exceval” of Kuraray Europe GmbH).

The mixtures of high-viscosity and low-viscosity polyvinyl acetals used according to the invention may be produced as solids by appropriate mixing of the polyvinyl acetals.

It is however also possible to produce the mixture by simultaneously acetalizing the corresponding polyvinyl alcohols and joint reprocessing. The mixing ratio can be varied within wide limits depending upon the desired flowability.

The polyvinyl alcohol, from which the high-viscosity polyvinyl acetal is to be produced, preferably has a viscosity of 20-110 mPas, most preferably 24-34 mPas, measured in accordance with DIN 53015 as a 4% solution in water at 20° C.

The polyvinyl alcohol, from which the low-viscosity polyvinyl acetal is to be produced, preferably has a viscosity of 2-15 mPas, most preferably 3-11 mPas, measured in accordance with DIN 53015 as a 4% solution in water at 20° C.

Polyvinyl acetals contain in addition to the acetal units also units resulting from vinyl acetate and vinyl alcohol. The high-viscosity and/or low-viscosity polyvinyl acetals used according to the invention preferably each have the same or a different polyvinyl alcohol content of 10-27% by weight, more preferably 13 to 21% by weight, and most preferably 13 to 17% by weight.

The polyvinyl acetate content of the high-viscosity and low-viscosity polyvinyl acetals is preferably in each case below 5% by weight, preferably below 3% by weight, and most preferably below 2% by weight. From the polyvinyl alcohol content and the residual acetate content, the degree of acetalization can be calculated.

The high-viscosity polyvinyl acetal and the low-viscosity polyvinyl acetal particularly preferably have the same polyvinyl alcohol content and optionally also have the same residual acetate content and degree of acetalization.

The high resistivity of the films required according to the invention is also altered by the type and/or quantity of the plasticizer used.

The films preferably have a plasticizer content of a maximum of 26% by weight, more preferably a maximum of 24% by weight, and most preferably a maximum of 22% by weight; for reasons of the processability of the film, the plasticizer content of the film should not fall below 15% by weight. Films or photovoltaic modules according to the invention can contain one or more plasticizers.

Particularly suitable according to the invention are plasticizers, the polarity of which, expressed by the formula 100×O/(C+H), is less than/equal to 9.4, O, C, and H representing the number of oxygen, carbon, and hydrogen atoms in the respective molecule. The following table shows plasticizers applicable according to the invention and polarity values thereof in accordance with the formula 100×O/(C+H).

| | | 100 × O/ |
|---|---|---|
| Name | Abbreviation | (C + H) |
| Di-2-ethylhexyl sebacate | (DOS) | 5.3 |
| Di-2-ethylhexyl adipate | (DOA) | 6.3 |
| Di-2-ethylhexyl phthalate | (DOP) | 6.5 |
| Dihexyl adipate | (DHA) | 7.7 |
| Dibutyl sebacate | (DBS) | 7.7 |
| Di-2-butoxy-ethyl sebacate | (DBES) | 9.4 |
| Triethylene glycol bis-2-ethyl | (3G8) | 9.4 |
| hexanoate | | |
| 1,2-Cyclohexane dicarboxylic | (DINCH) | 5.4 |
| acid diisononyl ester | | |

Less suitable are the following plasticizers

| | | 100 × O/ |
|---|---|---|
| Name | Abbreviation | (C + H) |
| Triethylene glycol bis-n- | 3G7 | 10.3 |
| heptanoate | | |
| Tetraethylene glycol bis-n- | 4G7 | 10.9 |
| heptanoate | | |
| Di-2-butoxy-ethyl adipate | DBEA | 11.5 |
| Di-2-butoxy-ethoxy-ethyl | DBEEA | 12.5 |
| adipate | | |

The adherence of polyvinyl acetal films to glass is usually adjusted by adding adhesion regulators such as for example the alkaline and/or alkaline earth salts of organic acids disclosed in WO 03/033583 A1. Potassium acetate and/or magnesium acetate turned out to be particularly suitable. Moreover, polyvinyl acetals often contain from the production process alkaline and/or alkaline earth salts of inorganic acids, such as for example sodium chloride.

Since salts also have an influence on the resistivity, the use of plasticizer-containing films based on polyvinyl acetal having less than 50 ppm, more preferably having less than 30 ppm, and most preferably having less than 20 ppm of metal ion is advantageous. This can be achieved by means of appropriate washing processes of the polyvinyl acetal and by using particularly effective antiblocking agents such as the magnesium, calcium, and/or zinc salts of organic acids (for example acetates) known to those skilled in the art.

Furthermore, the ion mobility, which might depend on the water content of the film, and hence the resistivity can be affected by the addition of fumed silica. The plasticizer-containing films based on polyvinyl acetal preferably contain 0.001 to 5% by weight of pyrogenic SiO₂.

The production and composition of suitable films is described in principle for example in EP 185 863 B1, EP 1 118 258 B1, WO 02/102591 A1, EP 1 118 258 B1, or EP 387 148 B1.

The lamination of the photovoltaic modules occurs by fusing the films, so that a bubble-free and waviness-free enclosure of the photosensitive semiconductor layer is obtained with the films.

In one variant of the photovoltaic modules according to the invention, the photosensitive semiconductor layers are applied to the covering d) (for example by evaporation coating, chemical vapor deposition, sputtering, or wet deposition) and bonded to the transparent front covering a) by means of a film c).

In another variant, the photosensitive semiconductor layers are applied to the transparent front covering a) and bonded to the back covering d) by means of film c).

Alternatively, the photosensitive semiconductor layers can be embedded between two films c) and bonded to the coverings a) and d) in this manner.

The thickness of the films based on plasticizer-containing polyvinyl acetal is usually 0.38, 0.51, 0.76, 1.14, 1.52, or 2.28 mm.

The transparent front covering a) normally consists of glass or PMMA. The back covering d) (so-called back sheet) of the photovoltaic module according to the invention can consist of glass, plastic, or metal or composites thereof, at least one of the supports possibly being transparent. It is also possible to design one or both of the coverings as laminated glass (i.e. as laminate made of at least two glass panels and one PVB film) or as insulation glass with a gas interspace. Naturally, combination of these measures is also possible.

The photosensitive semiconductor layers used in the modules do not need to have any special properties. Monocrystalline, polycrystalline, or amorphous systems can be used.

In case of thin-film solar modules, the photosensitive semiconductor layer is directly applied to the support. An encapsulation is not possible here. For this reason, the composite is assembled from a support (the back covering) with the photosensitive semiconductor layer and the transparent front covering using at least one sandwiched plasticizer-containing film based on polyvinyl acetal according to the invention and bonded by means of this film at an elevated temperature. Alternatively, the photosensitive semiconductor layer can be applied to the transparent front covering as support and bonded by means of at least one sandwiched plasticizer-containing film based on polyvinyl acetal according to the invention.

For lamination of the composite thus obtained, the methods known to those skilled in the art can be used with or without prior making of a pre-laminate.

So-called autoclave processes are performed at an elevated pressure of approximately 10 to 15 bar and temperatures of 130 to 145° C. over the course of approximately 2 hours. Vacuum bag or vacuum ring methods, for example according to EP 1 235 683 B1, operate at approximately 200 mbar and 130 to 145° C.

Vacuum laminators are preferably used for the production of the photovoltaic modules according to the invention. They consist of a heatable and evacuateable chamber, wherein laminated glasses may be laminated within 30-60 minutes. Reduced pressures of 0.01 to 300 mbar and temperatures of 100 to 200° C., most preferably 130-160° C., have proven to be of value in practice.

Alternatively, a composite assembled as described above can be pressed into the module according to the invention between at least one pair of rollers at a temperature of 60 to 150° C. Installations of this kind are known for the production of laminated glasses and usually have at least one heating tunnel upstream or downstream from the first pressing apparatus in installations having two pressing apparatuses.

A further subject matter of the invention is the use of plasticizer-containing films based on a mixture of a high-viscosity polyvinyl acetal and a low-viscosity polyvinyl acetal having a plasticizer content of a maximum of 26% by weight for the production of photovoltaic modules.

Plasticizer-containing films comprising polyvinyl acetal according to the invention having a plasticizer content of a maximum of 26% by weight and a mixture of at least one high-viscosity polyvinyl acetal having a viscosity of 40-300 mPas and at least one low-viscosity polyvinyl acetal having a viscosity of 5-500 mPas can be used for the production of laminated glasses such as windshields or window areas of buildings, facade element, roof areas, winter garden covering, sound insulating wall, balcony or balustrade element, or as component of window areas.

Photovoltaic modules according to the invention can be used as facade element, roof areas, winter garden covering, sound insulating wall, balcony or balustrade element, or as component of window areas.

### Measuring Procedures

The determination of the glass transition temperature of the film takes place by means of Differential Scanning Calorimetry (DSC) in accordance with DIN 53765 using a heating rate of 10 K/min in a temperature interval of −50° C.-150° C. A first heating ramp, followed by a cooling ramp, followed by a second heating ramp is used. The position of the glass transition temperature is determined from the measured curve associated with the second heating ramp in accordance with DIN 51007. The DIN midpoint (Tg DIN) is defined as intersection of a horizontal line at half step height with the measured curve. The step height is defined by the vertical distance of the two intersections of the middle tangent with the base lines of the measured curve before and after the glass transition.

The determination of the flow behavior of the film takes place as melt-flow index (melt mass flow rate: MFR) in accordance with ISO 1133 on a suitable instrument, for example from Gottfert Company, Model MI2. The MFR value is specified at 100° C. and 140° C. with the 2 mm nozzle and a weight loading of 21.6 kg in gram per 10 minutes (g/10 min).

The measurement of the volume resistivity of the film is performed in accordance with DIN IEC 60093 at a defined temperature and ambient humidity (23° C. and 85% RH) after the film has been conditioned for at least 24 h under these conditions. For the execution of the measurement, a plate electrode of type 302 132 from the company Fetronic GmbH and an instrument for resistivity measurement ISO-Digi 5kV from Amprobe Company was used. The testing voltage was 2.5 kV, the wait time after application of the testing voltage until acquisition of measured data was 60 sec. In order to guarantee sufficient contact between the flat plates of the measuring electrode and the film, the surface roughness R_{z} of the film should not be greater than 10 μm when measuring in accordance with DIN EN ISO 4287; i.e. the original surface of the PVB film has to be smoothed by thermal reembossing prior to the resistivity measurement, if necessary.

The polyvinyl alcohol and polyvinyl acetate contents of the polyvinyl acetals were determined in accordance with ASTM D 1396-92. Analysis of the metal ion content took place by means of atomic absorption spectroscopy (AAS).

The water or moisture content of the films is determined by the Karl Fischer method. In order to simulate the moistening behavior under humid conditions, the film is stored beforehand for 24 h at 23° C. and 85% RH. The method can be performed on both the unlaminated film and a laminated photovoltaic module as a function of the distance to the edge of the film.

### EXAMPLES

Mixtures of the following composition were prepared and the flowability and glass transition temperature thereof examined:

| | | MFR | | |
|---|---|---|---|---|
| | | 100/21.6/2 mm, | Tg, DSC, | |
| | | Div. F | Midpoint | Tg, DSC, |
| | | [g/10 min] | [° C.] | DIN [° C.] |
| 1 | 80% PVB1 | 0.13 | 27.23 | 25.51 |
| | 10% DBEEA | | | |
| | 10% 3G8 | | | |
| 2 | 80% PVB1 | 0.129 | 29.42 | 27.88 |
| | 20% 3G8 | | | |
| 3 | 65% PVB1 | 1.9 | 12.84 | 7.43 |
| | 17.5% DBEEA | | | |
| | 17.5% 3G8 | | | |
| 4 | 60% PVB1 | 0.49 | 28.56 | 27.13 |
| | 20% PVB2 | | | |
| | 20% 3G8 | | | |

DBEEA: di-2-butoxy-ethoxy-ethyl adipate
3G8 triethylene glycol bis-2-ethyl hexanoate
PVB1 high-viscosity polyvinyl butyral having a viscosity of 60-90 mPas (5% solution); polyvinyl alcohol content: 20.3% by weight; polyvinyl acetate content 1.1% by weight; degree of acetalization: 78.6%
PVB2 low-viscosity polyvinyl butyral having a viscosity of 60-90 mPas (10% solution), commercial product Mowital B45Hder Kuraray Europe GmbH; polyvinyl alcohol content 20.1% by weight; polyvinyl acetate content 2.3% by weight; degree of acetalization 72.6%

The viscosities were measured in accordance with DIN 53015 as 5 and 10% solution in ethanol (with 5% of water) at 20° C.

It becomes apparent that mixtures having a high plasticizer content have high flowability and a low glass transition temperature Tg (Ex. 3). Reducing the plasticizer content (Ex. 1 and 2) does indeed cause a significant increase of the glass transition temperature but also worsens the flowability at the same time. The use of plasticizers of low polarity (Ex. 2 vs. Ex. 1) causes a further increase of the glass transition temperature but has basically no effect on the flowability.

Ex. 4 shows that an increase of both the glass transition temperature and the flowability can be achieved by means of the mixtures of high-viscosity and low-viscosity polyvinyl acetals used according to the invention.

1.-13. (canceled)

14. A photovoltaic module comprising a laminate of
a) a transparent front covering
b) one or more photosensitive semiconductor layers
c) at least one plasticizer-containing film based on polyvinyl acetal, and
d) a back covering,
wherein the plasticizer-containing films based on polyvinyl acetal c) have a plasticizer content of a maximum of 26% by weight and comprise a mixture of at least one high-viscosity polyvinyl acetal having a viscosity of 40-300 mPas and at least one low-viscosity polyvinyl acetal having a viscosity of 5-500 mPas, the low-viscosity polyvinyl alcohol having a lower viscosity than the high-viscosity polyvinyl alcohol.

15. The photovoltaic module of claim 14, wherein the high-viscosity polyvinyl acetal has a viscosity of 50-100 mPas and the low-viscosity polyvinyl acetal has a viscosity of 10-100 mPas.

16. The photovoltaic module of claim 15, wherein the high-viscosity polyvinyl acetal and the low-viscosity polyvinyl acetal are used in a weight ratio with respect to one another of 1:1 to 19:1.

17. The photovoltaic module of claim 14, wherein the high-viscosity polyvinyl acetal has a polyvinyl alcohol content of 10-27% by weight.

18. The photovoltaic module of claim 14, wherein the low-viscosity polyvinyl acetal has a polyvinyl alcohol content of 10-27% by weight.

19. The photovoltaic module of claim 14, wherein the high-viscosity polyvinyl acetal and the low-viscosity polyvinyl acetal have the same polyvinyl alcohol content.

20. The photovoltaic module of claim 14, wherein one or more compounds, the polarity of which, expressed by the quotient O/(C+H), is less than/equal to 9.4, O, C, and H representing the number of oxygen, carbon, and hydrogen atoms in the respective molecule, are used as plasticizer.

21. The photovoltaic module of claim 14, wherein one or more compounds from the group of di-2-ethylhexyl sebacate (DOS), di-2-ethylhexyl adipate (DOA), di-2-ethylhexyl phthalate (DOP), dihexyl adipate (DHA), dibutyl sebacate (DBS), di-2-butoxy-ethyl sebacate (DBES), triethylene glycol bis-2-ethyl hexanoate (3G8) are used as plasticizer.

22. The photovoltaic module of claim 14, wherein the plasticizer-containing film based on polyvinyl acetal contains less than 50 ppm of metal ions.

23. The photovoltaic module of claim 14, wherein the plasticizer-containing film based on polyvinyl acetal contains 0.001 to 5% by weight of SiO₂.

24. The photovoltaic module of claim 14, wherein polyvinyl butyral is used as high-viscosity polyvinyl acetal and low-viscosity polyvinyl acetal.

25. A plasticizer-containing film comprising polyvinyl acetal, wherein the films have a plasticizer content of a maximum of 26% by weight and comprise a mixture of at least one high-viscosity polyvinyl acetal having a viscosity of 40-300 mPas and at least one low-viscosity polyvinyl acetal having a viscosity of 5-500 mPas, the viscosity of the high-viscosity polyvinyl alcohol being higher than the viscosity of the low-viscosity polyvinyl alcohol.

26. In a process for the production of photovoltaic modules wherein a plasticizer-containing film is employed, the improvement comprising employing as at least one plasticizer-containing film, a plasticizer-containing film comprising a mixture of a high-viscosity polyvinyl acetal and a low-viscosity polyvinyl acetal having a plasticizer content of a maximum of 26% by weight for the production of photovoltaic modules.
